(19) United States
(12) Patent Application Publication
(10) Pub. No.: US 2026/0132017 A1
(43) Pub. Date: May 14, 2026

(54) MEMS COMPONENT COMPRISING A MEMS ELEMENT HAVING A CAVITY AND COMPRISING AN ASIC COMPONENT

(71) Applicant: Robert Bosch GmbH, Stuttgart (DE)

(72) Inventor: Hans-Peter Waible, Flein (DE)

(21) Appl. No.: 19/321,786

(22) Filed: Sep. 8, 2025

(30) Foreign Application Priority Data
Nov. 13, 2024 (DE) 10 2024 210 892.8

(51) Int. Cl. B81B 7/00; B81C 1/00

(52) U.S. Cl. CPC B81B 7/0038; B81C 1/00285; B81B 2203/0315; B81B 2207/015; B81B 2207/03; B81B 2207/07; B81B 2207/094; B81C 2201/0181

(57) ABSTRACT

A MEMS component including a MEMS element having a cavity, wherein the cavity is bounded at least partially by an ASIC component. The ASIC component includes, between a top and bottom layer, multiple conductor track layers one above the other along a y-direction. The conductor track layers are connected to circuit elements of the ASIC component and/or a sensor element and/or an actuator element of the MEMS element. The top layer of the ASIC component adjoins the cavity. The conductor track layers includes at least one first conductor track layer and at least one second conductor track layer. The first conductor track layer is disposed between the second conductor track layer and the top layer. The first conductor track layer includes at least one conductor track. The conductor track includes a layer stack having an aluminum layer and a titanium layer disposed one above the other in the y-direction.

### CROSS REFERENCE

The present application claims the benefit under 35 U.S.C. § 119 of Germany Patent Application No. DE 10 2024 210 892.8 filed on Nov. 13, 2024, which is expressly incorporated herein by reference in its entirety.

### FIELD

The present invention relates to a MEMS component comprising a MEMS element having a cavity, wherein the cavity is bounded at least partially by an ASIC component.

### BACKGROUND INFORMATION

German Patent Application No. DE 10 2004 020 685 B3 describes a MEMS component having a cavity, wherein a getter layer is provided in the cavity in order to absorb certain gas molecules.

### SUMMARY

According to an example embodiment of the present invention, a MEMS component comprising a MEMS element having a cavity, wherein an ASIC component at least partially bounds the cavity, is designed in such a way that a pressure change in the cavity due to gases diffusing out in the ASIC component is reduced, in particular avoided.

An object of the present invention is achieved by certain features disclosed herein.

Advantageous example embodiments of the present invention are disclosed herein.

An advantage of the MEMS component according to the present invention is that outgassing of hydrogen from the ASIC component into the cavity of the MEMS element is reduced, in particular avoided.

According to an example embodiment of the present invention, this is achieved because the ASIC component comprises a conductor track comprising a titanium layer, the titanium layer being disposed between the cavity and a further conductor track. The titanium layer has a thickness which is preferably greater than 40 nm. The second conductor track system (i.e., conductor track and insulation) comprises copper, or the second conductor track comprises copper or is configured as a copper conducting track, and from the hydrogen may outgas from the copper. In addition, the ASIC component may comprise a copper conducting track stack having multiple copper conducting tracks from which hydrogen may outgas. The hydrogen that outgasses from the one or more copper conducting tracks and diffuses towards the cavity is at least partially, in particular completely, bound by the titanium layer. Thus, the titanium layer is a getter layer for binding the hydrogen. Depending on the chosen embodiment, the titanium layer may also have larger thicknesses in order to sufficiently bind the hydrogen from the second conductor track.

The titanium of the titanium layer has the property of being able to form hydrides, in the case of which hydrogen is incorporated into the titanium layer with a release of energy. The thickness and/or the width of the titanium layer may be adapted to the expected amount of hydrogen. Preferably, so much titanium is present that all of the hydrogen outgassing from the at least one second conductor track or the copper conducting track stack can be bound.

According to an example embodiment of the present invention, a top layer of the ASIC component adjoins the cavity of the MEMS element. Sensor elements and/or actuator elements may be disposed adjacent to or in the cavity or may be connected to the cavity by a conducting channel.

According to an example embodiment of the present invention, the ASIC component comprises, between the top layer and a bottom layer, multiple conductor track layers disposed one above the other. The conductor tracks of the conductor track layers may be connected to circuit elements of the ASIC component and/or to a sensor element and/or actuator element of the MEMS element. The ASIC component comprises a first conductor track layer disposed between the top layer and the second conductor track layer. The first conductor track layer comprises at least one first conductor track, the first conductor track comprising a layer stack having at least an aluminum layer and a titanium layer. The titanium layer is disposed between the aluminum layer and the second conductor track layer and thus faces the second conductor track layer. The second conductor track layer comprises a second conductor track having copper or is configured as a copper layer. Thus, the titanium layer serves as a getter layer for binding hydrogen which may outgas from the copper conducting track stack of the second conductor track and diffuse towards the cavity. In this way, the penetration of outgassing hydrogen into the cavity is reduced or prevented.

In one example embodiment of the present invention, the titanium layer has a base area in a first x-z-plane, and the second conductor track has a base area in a second x-z-plane. In a perpendicular projection along the y-direction, the base area of the titanium layer is disposed above the second conductor track over at least 50% of a length of the second conductor track and covers in particular the entire width of the second conductor track. Thus, in a perpendicular projection along the y-direction, the titanium layer of the first conductor track preferably covers the entire width of the second conductor track over at least 50% of a length of the second conductor track. In this way, coverage of the second conductor track by the titanium layer of the first conductor track is achieved so that the titanium layer has relatively high efficiency as a getter layer.

Depending on the chosen embodiment of the present invention, in the perpendicular projection the titanium layer also covers more than 50% of the length of the second conductor track, in particular 70% or more, in particular 90% or more of the length of the second conductor track. Preferably, the titanium layer covers the entire width of the second conductor track, in particular at least on each side the second conductor track by 5%, in particular 10% of the width of the second conductor track. The further the titanium layer covers the width of the second conductor track in the perpendicular projection, the better the effect of the titanium layer as a getter layer is.

In a further example embodiment of the present invention, the second conductor track layer comprises a further second conductor track next to the second conductor track, the further second conductor track likewise comprising or being configured as a copper layer. The second and further second conductor tracks are laterally spaced apart from each other by an intermediate region. The base area of the titanium layer is configured, in a perpendicular projection along the y-direction, such that the base area of the titanium layer covers the base area of the second conductor track, the intermediate region between the second conductor track and the further second conductor track, and the base area of the further second conductor track. In this way, not only the second conductor track and the further second conductor track but also the intermediate region between the two second conductor tracks are covered by the titanium layer against outgassing of hydrogen towards the cavity. In this way, an improved effect of the titanium layer as a getter layer is achieved.

In a further example embodiment of the present invention, a barrier layer is provided between the cavity and the first conductor track layer. The barrier layer is configured to reduce, in particular prevent, outgassing of argon from the first conductor track into the cavity. For example, the barrier layer comprises a silicon nitride layer, the silicon nitride layer in particular having a thickness of at least 40 nm and for example being configured as a sputtered layer. By means of the barrier layer, outgassing of argon into the cavity is reduced, in particular prevented.

In a further example embodiment of the present invention, the MEMS component comprises a via contact line which is led to the titanium layer of the first conductor track. The titanium layer has a reduced thickness in the y-direction in the region of the via contact line in comparison with a lateral region adjacent in the x-z-plane. In this way, an electrical resistance between the via contact line and the aluminum layer is reduced. The reduced thickness is in particular realized by a recess in the titanium layer, in which the via contact line is led. In this way, despite a substantially relatively thick titanium layer, the ohmic resistance of the electrically conductive connection between the via contact line and the aluminum layer can be reduced. The aluminum layer is provided to carry a substantial proportion of the current of the first conductor track.

In one example embodiment of the present invention, the via contact line comprises tungsten and is in particular formed of tungsten. Tungsten is suitable for a safe and low-resistance configuration of the via contact line.

Depending on the selected embodiment, the titanium layer may have a thickness of greater than 100 nm, in particular greater than 150 nm or greater than 180 nm, in the y-direction. The greater the thickness of the titanium layer is, the more titanium is available for the getter function for binding hydrogen.

In a further example embodiment of the present invention, a further titanium layer is disposed between the aluminum layer of the first conductor track layer and the top layer, the further titanium layer having a thickness of less than 20 nm, in particular less than 15 nm. The further titanium layer serves more to reliably construct the first conductor track and less as a getter layer.

In a further example embodiment of the present invention, the ASIC component comprises a further first conductor track layer between the first conductor track layer and the second conductor track layer, wherein the further first conductor track layer comprises at least one further first conductor track, wherein the further first conductor track comprises a layer stack having an aluminum layer and a titanium layer. The aluminum layer is disposed on the titanium layer of the further first conductor track and between the titanium layer of the further first conductor track and the first conductor track layer. The titanium layer of the further first conductor track has a thickness of greater than 40 nm and serves as a getter layer for binding hydrogen which may outgas from at least one or more second conductor tracks having copper, in particular from a layer stack having multiple second conductor track layers. This too can reduce or prevent the penetration of the outgassing hydrogen into the cavity.

Another advantage of the MEMS component of the present invention is that the component withstands. without significant impairment of the electrical properties, sequential temperature-stress processes which occur, for example, in standard soldering, overmolding or high-temperature storage. In this way, an internal pressure of the cavity can reliably be maintained over the long term.

According to an example embodiment of the present invention, the MEMS component comprises: a MEMS (micro-electromechanical system) element having micro-mechanical structures and having a cavity; and an ASIC (application-specific integrated circuit) component having circuit components which cooperate with the micro-mechanical structure of the MEMS element. The MEMS element is mounted on the ASIC component such that the micro-mechanical structure of the MEMS element is disposed in the cavity between the MEMS element and the ASIC component.

Embodiment examples of the MEMS component of the present invention are explained in more detail below with reference to figures.

### BRIEF DESCRIPTION OF THE DRAWINGS

FIG. 1 shows a schematic cross-section through a MEMS component having a MEMS element with a cavity and having an ASIC component, according to an example embodiment of the present invention.

FIG. 2 shows a schematic plan view of the ASIC component, according to an example embodiment of the present invention.

FIG. 3 shows a more detailed view of the ASIC component, in a schematic cross-section, according to an example embodiment of the present invention.

FIG. 4 shows a plan view of the first conductor track of the ASIC component, in a schematic illustration, according to an example embodiment of the present invention.

FIG. 5 shows a schematic cross-section through a further embodiment of the ASIC component, according to an example embodiment of the present invention.

FIG. 6 shows a schematic partial cross-section through a via contact line of an ASIC component, according to an example embodiment of the present invention.

FIG. 7 shows a schematic cross-sectional illustration of another embodiment of the ASIC component, according to an example embodiment of the present invention.

### DETAILED DESCRIPTION OF EXAMPLE EMBODIMENTS

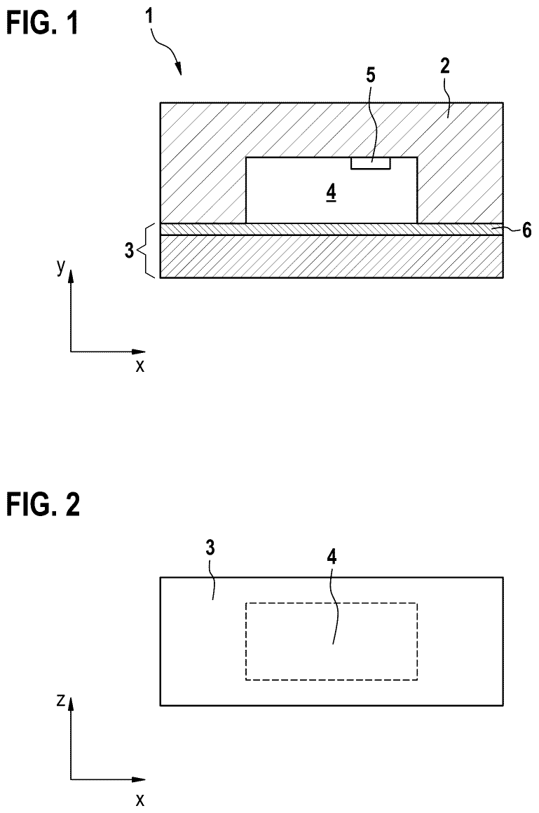

FIG. 1 shows, in a schematic illustration, a cross-section through a MEMS component 1, which comprises a MEMS element 2 and an ASIC component 3. A cavity 4 is formed between the MEMS element 2 and the ASIC component 3. The cavity 4 is bounded by the MEMS element 2 and at least partially by the ASIC component 3. Sensor elements and/or actuator elements 5 of MEMS element 2 may be disposed adjacent to or in the cavity 4 or may at least be connected to the cavity 4 by a channel. The ASIC component 3 comprises a top layer 6 which is at least partially directly adjacent to the cavity 4.

FIG. 2 shows a view of the ASIC component 3 in a schematic illustration, wherein the cavity 4 is schematically indicated by means of dashed lines. In the illustrated embodiment example, the cavity 4 is bounded on five sides by the MEMS element 2 and on one side by the ASIC component 3.

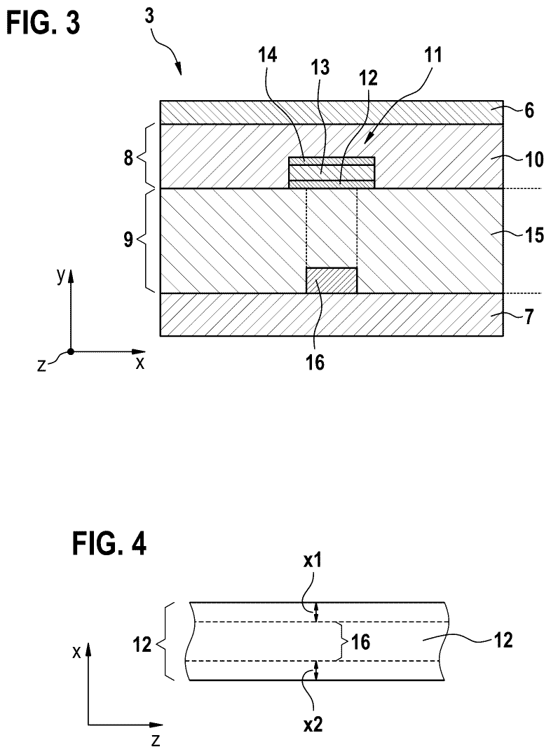

FIG. 3 shows, in a schematic cross-section, a partial cross-section of the ASIC component 3, wherein the ASIC component 3 comprises a first conductor track layer 8 adjacent to the top layer 6. A second conductor track layer 9 adjoins the first conductor track layer 8 along the y-direction. A bottom layer 7 adjoins the second conductor track layer 9. Electrical and/or electronic circuits of the ASIC component may be integrated in the bottom layer 7.

The first conductor track layer 8 comprises a first insulation layer 10 in which a first conductor track 11 is embedded. The first conductor track 11 comprises, adjacent to the second conductor track layer 9, a first layer 12 comprising or formed of titanium. Depending on the chosen embodiment, the first layer 12 may also consist of or comprise a layer stack consisting of the layer sequence titanium nitride, titanium, titanium nitride. A first conductor layer 13 comprising or formed of aluminum is disposed on the first layer 12. A first top layer 14 comprising titanium and in particular formed of a layer stack of the layer sequence titanium nitride, titanium, titanium nitride may be disposed on the first conduction layer 13.

The titanium layer of the first layer 12 may have a thickness of between 40 nm and 200 nm and thicker. The titanium layer of the first layer 12 forms a getter layer for hydrogen that diffuses. The titanium nitride layers of the first layer may have a thickness of less than 10 nm and may have, for example, the function of an adhesion promoter or of a separation layer for suppressing the mixing of materials.

The second conductor track layer 9 comprises a second insulation layer 15 in which a second conductor track 16 is embedded. The second conductor track comprises or is formed of copper. The second conductor track 16 and the second insulation layer 15 are disposed in the bottom layer 7.

The first layer 12 has a width along the x-direction that is wider than the width of the second conductor track 16. In addition, the first layer 12 is disposed between the cavity 4 and the second conductor track 16 in such a way that, in a projection along the y-direction, the first layer 12 covers the entire width of the second conductor track 16. Preferably, the titanium layer of the first layer 12 protrudes beyond the second conductor track 16 laterally on both sides along the x-direction. In this way, good getter action against diffusion of hydrogen into the cavity 4 is achieved.

In addition, the ASIC component 3 may be configured in such a way that multiple first conductor tracks 11 are disposed next to each other in the first conductor track layer 8. In addition, ASIC component 3 may be configured in such a way that multiple second conductor tracks 16 are disposed next to each other in the second conductor track layer 9. The design of the first conductor tracks 11 may be identical or may also vary.

Similarly, the second conductor tracks 16 may also be identically configured or may vary in design from one another.

The top layer 6 may be or comprise a barrier layer which reduces, in particular prevents, outgassing of carrier gas, e.g., argon, from the first conductor track layer into the cavity. For example, the top layer 6 may comprise a silicon nitride layer as a barrier layer. The silicon nitride layer may in particular have a thickness of, for example, 50 nm to 100 nm along the y-direction. The barrier layer, in particular the silicon nitride layer, may be configured as a sputtered layer.

FIG. 4 shows, in a schematic illustration, a plan view of the titanium layer of the first layer 12, wherein the second conductor track 16 lying therebelow is shown in the form of dashed lines. The first conductor track 11 and the first layer 12 extend along the z-direction in the longitudinal direction, and the second conductor track 16 also extends along the z-direction in the longitudinal direction.

The titanium layer of the first layer 12 protrudes beyond the second conductor track 16 laterally, i.e., along the x-direction, at least by a specified distance x1, x2. The specified distances x1, x2 may be 1 to 5% or more of the width of the second conductor track 16 in the x-direction. The more the first conductor track 11 protrudes beyond the second conductor track 16 along the x-direction on both sides, the better a shielding action against the diffusion of hydrogen into the cavity is.

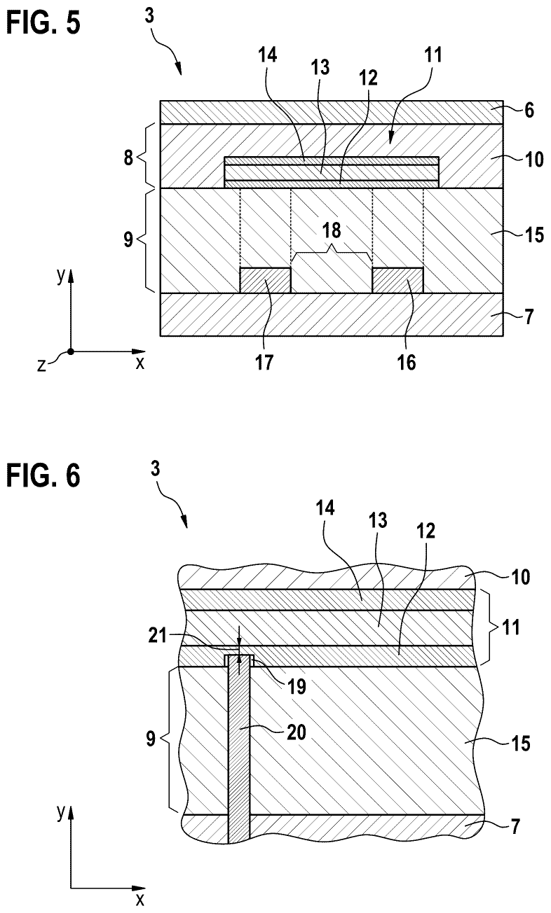

FIG. 5 shows a schematic cross-section through a further embodiment of the ASIC component 3. In this embodiment, the second conductor track layer 9 comprises a further second conductor track 17, which is spaced from the second conductor track 16 laterally in the x-direction by an intermediate region 18. The further second conductor track 17 likewise comprises or is formed of copper. In this embodiment, the first conductor track 11 is configured with the titanium layer of the first layer 12, the first conduction layer 13 and the first top layer 14 similarly to the embodiment of FIG. 3, but covers, in a projection in the y-direction, the second conductor track 16, the intermediate region 18 between the second conductor track 16 and the further second conductor track 17, and the further second conductor track 17. In addition, the first layer 12 of the first conductor track 11 protrudes beyond the second conductor track 16 and the further second conductor track 17 laterally along the x-direction. In this way, not only the second conductor track 16 and the further second conductor track 17 but also the intermediate region 18 between the second conductor track 16 and the further second conductor track 17 are covered by the titanium layer of the first layer 12 of the first conductor track 11 towards the cavity. In this way, improved protection against diffusion of hydrogen into the cavity 4 is achieved.

FIG. 6 shows part of the ASIC component 3 in a schematic partial sectional view, wherein an electrically conductive via contact line 20 is led from the bottom layer 7 through the second insulation layer 15 of the second conductor track layer 9 for electrical contacting with the first conduction layer 13. To reduce the electrical resistance of the first layer 12 comprising titanium, the first layer 12 has a recess 19 filled with the conducting track material 11. Thus, a remaining thickness 21 of the first layer 12 which is formed between the end of the via contact line 20 and the first conduction layer 13 is significantly reduced and is for example in the range of 5% to 30% of the layer thickness of the titanium layer of the first layer 12.

Depending on the chosen embodiment, the via contact line 20 may comprise or be formed of tungsten.

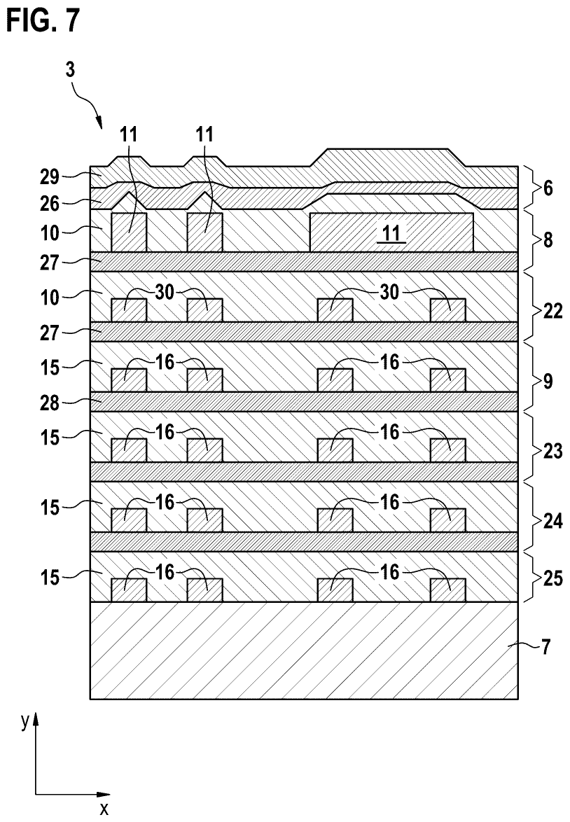

FIG. 7 shows a further embodiment of an ASIC component 3 in a cross-section and in a schematic illustration. In this embodiment, the top layer 6 comprises a top insulation layer 25 [sic]¹ and a barrier layer 26. The first conductor track layer 8 comprises a bottom insulation layer 27 on which the first conductor tracks 11 and the first insulation layer 10 are disposed. ¹ [Translator's note: According to FIG. 7, the reference sign should likely read “29”.]

In addition, a further first conductor track layer 22, which likewise comprises a first insulation layer 10, a bottom insulation layer 27 and further first conductor tracks 30, is disposed adjacent to the first conductor track layer 8. The conductor tracks 11 of the first conductor track layer 8 and the further first conductor tracks 30 of the further first conductor track layer 22 may have the same layer structure, in particular a first layer 12 having titanium and a first conduction layer 13 having aluminum, as described with reference to FIG. 3.

The further first conductor track layer 22 is disposed on the second conductor track layer 9. In the illustrated embodiment example, the second conductor track layer 9 comprises a second bottom insulation layer 28, a second insulation layer 15 and multiple second conductor tracks 16. In the illustrated embodiment, further second conductor track layers 23, 24, 25 are arranged, which are configured similarly to the second conductor track layer 9. The second conductor track layer 9 and the further second conductor track layers 23, 24, 25 may have the same construction, in particular second conductor tracks 16 having copper.

The second conductor track layers 9, 23, 24, 25 have the advantage of achieving high wiring density with low parasitic wiring capacitances. The high wiring density with narrow conductor tracks significantly increases so-called utilization of the digital gates. Thus, high area efficiency is enabled.

The first conductor track layers 8, 22 have the advantage that, by means of the relatively thick titanium layers, i.e., the first layers 12, relatively good getter layers are provided for binding hydrogen that outgasses from the copper conductor tracks lying therebelow. Despite the incorporation of hydrogen in titanium, the electrical properties of titanium do not change much. The layer thickness of the first layer 12 is preferably adapted to the expected amount of hydrogen gas. The titanium layer is applied as a layer in the proposed MEMS component so that no extra masks or additional process steps are required.

Viewed in the projection along the y-direction, the first layers 12 of the first conductor track layer 8 preferably cover as much of the areas of the second conductor tracks 16 of the second conductor track layers 9 as possible.

The via contact line used, which comprises tungsten, prevents the copper from leaking into the aluminum material of the first conduction layer 13.

In addition, cratering during wafer bonding may be reduced or eliminated by means of a solid tungsten frame.

The proposed MEMS component allows optimization of the layer structure, wherein outgassing of hydrogen is reduced and nevertheless a high wiring density in the ASIC component is enabled.

The aluminum layer of the first conduction layer 13 may have a thickness in the range of 250 to 350 nm, or up to 1 μm and more.

The insulation layers may be, for example, oxide layers, in particular silicon oxide layers or silicon nitride layers.

The second conductor tracks 16, which comprise or are formed of copper, may have a width of less than 100 nm or more. The first layers 12 and the first conduction layers 13 may have a width of 150 nm or wider.

What is claimed is:

1. A MEMS component, comprising:
a MEMS element having a cavity; and
an ASIC component, wherein the cavity is bounded at least partially by the ASIC component;
wherein the ASIC component includes, between a top layer and a bottom layer, multiple conductor track layers one above the other along a y-direction,
wherein the conductor track layers are connected to circuit elements of the ASIC component and/or to a sensor element and/or to an actuator element of the MEMS element,
wherein the top layer of the ASIC component adjoins the cavity,
wherein the conductor track layers include at least one first conductor track layer and at least one second conductor track layer,
wherein the first conductor track layer is disposed between the second conductor track layer and the top layer,
wherein the first conductor track layer includes at least one first conductor track,
wherein the first conductor track includes a layer stack having an aluminum layer and a titanium layer disposed one above the other in the y-direction,
wherein the titanium layer is disposed between the second conductor track layer and the aluminum layer, and the titanium layer has a thickness of greater than 40 nm in the y-direction,
wherein the second conductor track layer includes a second conductor track having copper, and
wherein the titanium layer is provided as a getter layer for binding hydrogen, wherein the hydrogen may outgas from the copper layer, wherein the titanium layer reduces or prevents the penetration of outgassing hydrogen into the cavity.

2. The MEMS component according to claim 1, wherein the titanium layer of the first conductor track has a base area in a first x-z-plane, wherein the second conductor track has a base area in a second x-z-plane, wherein, in a perpendicular projection along the y-direction, the base area of the titanium layer covers the base area of the second conductor track over at least 50% of a length of the second conductor track and over an entire width of the second conductor track.

3. The MEMS component according to claim 2, wherein the second conductor track layer includes a further second conductor track next to the second conductor track, wherein the second conductor track includes copper, wherein the second and the further second conductor tracks are laterally spaced apart by an intermediate region, wherein, in a perpendicular projection along the y-direction, the base area of the titanium layer extends over the base area of the second conductor track, the intermediate region and the base area of the further second conductor track, so that the intermediate region between the two second conductor tracks is also covered against outgassing of hydrogen towards the cavity.

4. The MEMS component according to claim 1, wherein, between the cavity and the first conductor track layer, a barrier layer is provided which prevents outgassing of argon from the first conductor track layer into the cavity.

5. The MEMS component according to claim 4, wherein the barrier layer includes a silicon nitride layer, wherein the silicon nitride layer has a thickness of at least 40 nm and is configured as a sputtered layer.

6. The MEMS component according to claim 1, wherein a via contact line is led to the titanium layer, wherein the titanium layer has a reduced thickness in the y-direction in a region of the via contact line in comparison with a region laterally adjacent in an x-z-plane in order to produce a reduced electrical resistance between the via contact line and the aluminum layer, wherein the reduced thickness is realized by a recess in the titanium layer, wherein the via contact line is arranged in the recess of the titanium layer.

7. The MEMS component according to claim 6, wherein the via contact line includes tungsten.

8. The MEMS component according to claim 1, wherein the titanium layer has a thickness of greater than 100 nm.

9. The MEMS component according to claim 1, wherein a further titanium layer is disposed between the aluminum layer of the first conductor track layer and the top layer, wherein the further titanium layer has a thickness of less than 20 nm.

10. The MEMS component according to claim 1, wherein a further first conductor track layer is disposed between the first conductor track layer and the second conductor track layer, wherein the further first conductor track layer includes at least one further first conductor track, wherein the first conductor track includes a layer stack having an aluminum layer and a titanium layer disposed one above the other along the y-direction, wherein the titanium layer is disposed between the second conductor track layer and the aluminum layer of the further first conductor track layer, and wherein the titanium layer has a thickness of greater than 40 nm, and wherein the titanium layer is provided as a getter layer for binding hydrogen which outgasses from the copper layer of the second conductor track layer, in order to reduce or prevent the penetration of the outgassing hydrogen into the cavity.
